(19) United States
(12) Patent Application Publication
(10) Pub. No.: US 2024/0320412 A1
(43) Pub. Date: Sep. 26, 2024

(54) PROCESS PROXIMITY CORRECTION METHOD BASED ON DEEP LEARNING, AND SEMICONDUCTOR MANUFACTURING METHOD COMPRISING THE PROCESS PROXIMITY CORRECTION METHOD

(71) Applicant: Samsung Electronics Co., Ltd., Suwon-si (KR)

(72) Inventor: Sooyong LEE, Suwon-si (KR)

(73) Assignee: Samsung Electronics Co., Ltd., Suwon-si (KR)

(21) Appl. No.: 18/492,206

(22) Filed: Oct. 23, 2023

(30) Foreign Application Priority Data
Mar. 24, 2023 (KR) 10-2023-0039306

(51) Int. Cl. G06F 30/398; G06F 30/392

(52) U.S. Cl. CPC G06F 30/398; G06F 30/392

(57) ABSTRACT

A deep learning-based process proximity correction method includes receiving a first layout associated with an After Cleaning Inspection (ACI), the first layout including a plurality of patterns associated with manufacturing a semiconductor device, generating a predictive model based on the plurality of patterns, through deep learning, generating a layout associated with an After Development Inspection (ADI) by correcting the first layout, and predicting an ACI using the layout of ADI, through the predictive model.

### CROSS-REFERENCE TO RELATED APPLICATION

This application is based on and claims priority under 35 U.S.C. § 119 to Korean Patent Application No. 10-2023-0039306, filed on Mar. 24, 2023, in the Korean Intellectual Property Office, the disclosure of which is incorporated by reference herein in its entirety.

### BACKGROUND

Various example embodiments to a method of manufacturing a semiconductor device, and more particularly, to a process proximity correction (PPC) method and/or a method of manufacturing a semiconductor device including the PPC method.

In a semiconductor process, a photolithography process using a mask may be performed to form a pattern on a semiconductor substrate such as a wafer. A mask may refer to a pattern transfer body in which a pattern shape of an opaque material is formed on a transparent base layer material. In order to manufacture a mask, a layout for a particular pattern is designed, and then optical proximity-corrected layout data obtained through optical proximity correction (OPC) is transmitted as mask tape-out (MTO) design data. Thereafter, mask data preparation (MDP) may be performed based on the MTO design data, and an exposure process and/or the like may be performed on a substrate for a mask.

### SUMMARY

Various example embodiments provide a deep learning-based process proximity correction method with improved reliability, and/or a semiconductor device manufacturing method including the process proximity correction method.

However, objectives to be solved or improved upon by example embodiments are not limited to the above-mentioned ones, and other objectives could be clearly understood by those of ordinary skill in the art from the description below.

According to some example embodiments, there is provided a deep learning-based process proximity correction method including receiving a first layout associated with an After Cleaning Inspection (ACI), the first layout including a plurality of patterns associated with manufacturing a semiconductor device, generating a predictive model based on the plurality of patterns, through deep learning generating a layout of After Development Inspection (ADI) by correcting the first layout, and predicting ACI by using the layout of the ADI through the predictive model.

Alternatively or additionally, there is provided a deep learning-based process proximity correction method including receiving a first layout associated with an ACI, the first layout including a plurality of patterns associated with manufacturing a semiconductor device, generating a second layout by performing deep learning (DL)-process proximity correction (PPC) based on the plurality of patterns of the first layout, and generating a third layout by performing optical proximity correction (OPC) on the second layout.

Alternatively or additionally, there is provided a mask manufacturing method including receiving a first layout including a plurality of patterns associated with manufacturing a semiconductor device, generating a second layout by performing deep learning-based process proximity correction on the first layout, generating a third layout by performing optical proximity correction on the second layout, transmitting the third layout as mask tape-out (MTO) design data, preparing mask data based on the MTO design data, and exposing a substrate of a mask based on the mask data.

### BRIEF DESCRIPTION OF THE DRAWINGS

Various example embodiments will be more clearly understood from the following detailed description taken in conjunction with the accompanying drawings in which:

FIG. 1 is a block diagram illustrating a computing device according to some example embodiments;

FIG. 2 is a flowchart of a process of generating a layout, performed by a semiconductor process deep learning module of FIG. 1;

FIGS. 3 to 5 are conceptual diagrams of layouts in respective operations of FIG. 2, wherein FIG. 3 corresponds to a first layout, FIG. 4 corresponds to a second layout, and FIG. 5 corresponds to a third layout;

FIG. 6 is a detailed flowchart of an operation of generating the second layout of FIG. 2;

FIG. 7 is a detailed flowchart of an operation of correcting the first layout of FIG. 6;

FIG. 8 is a diagram illustrating setting an input order of a plurality of tokens according to some example embodiments;

FIG. 9 is a diagram illustrating configuring a deep learning algorithm, according to some example embodiments; and

FIG. 10 is a flowchart schematically illustrating a process of a mask manufacturing method, according to some example embodiments.

### DETAILED DESCRIPTION OF VARIOUS EXAMPLE EMBODIMENTS

Hereinafter, inventive concepts will be described more fully with reference to the accompanying drawings, in which various example embodiments are shown. In the drawings, like elements are labeled like reference numerals and repeated description thereof will be omitted.

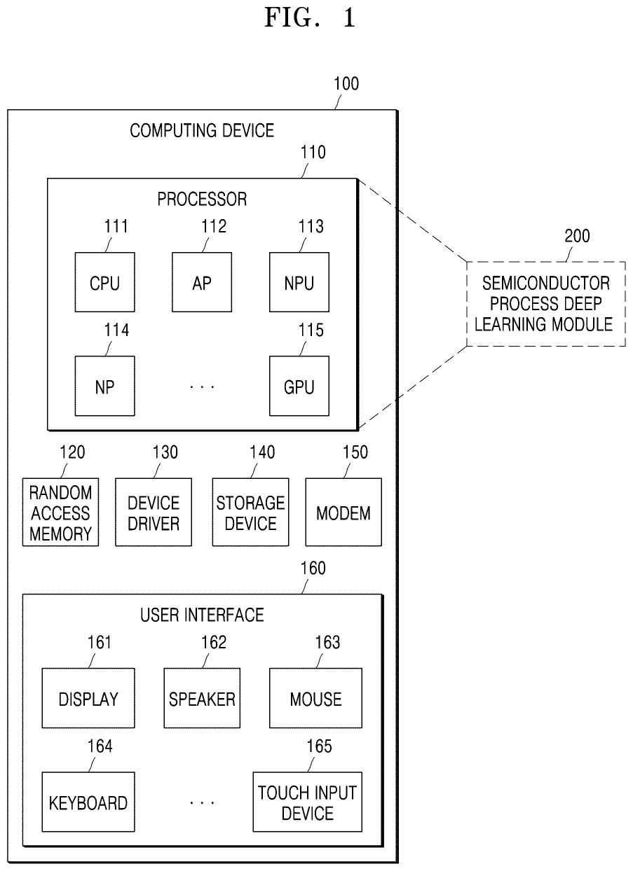

FIG. 1 is a block diagram illustrating a computing device according to some example embodiments.

Referring to FIG. 1, a computing device 100 may include one or more processors 110, random access memory 120, a device driver 130, a storage device 140, a modem 150, and a user interface 160.

As used herein, the term processor may indicated or refer to one processor that performs variously defined functions or a plurality of processors that collectively perform the defined functions such that the execution of the individual defined functions may be divided amongst such processors.

At least one of the plurality of processors 110 may execute a semiconductor process deep learning module 200. The semiconductor process deep learning module 200 may generate a layout for manufacturing a semiconductor device based on deep learning. For example, the semiconductor process deep learning module 200 may be implemented in the form of instructions (or pieces of code) executed by at least one of the plurality of processors 110. At least one processor may load instructions (or pieces of code) of the semiconductor process deep learning module 200 into the random access memory 120.

Alternatively or additionally, at least one processor 110 may be manufactured to implement the semiconductor process deep learning module 200. Alternatively or additionally, the at least one processor 110 may be manufactured to implement various deep learning modules. The at least one processor 110 may implement the semiconductor process deep learning module 200 by receiving information corresponding to the semiconductor process deep learning module 200.

The plurality of processors 110 may include, for example, at least one general-purpose processor such as a central processing unit (CPU) 111 and/or an application processor (AP) 112. The plurality of processors 110 may also include at least one special-purpose processor, such as a neural processing unit (NPU) 113, a neuromorphic processor (NP) 114, a graphics processing unit (GPU) 115, and the like. The plurality of processors 110 may include two or more processors of the same type; example embodiments are not limited thereto.

The random access memory 120 may be used as an operating memory of the plurality of processors 110 and may be used as a main memory or system memory of the computing device 100. The random access memory 120 may include volatile memory such as dynamic random access memory and/or static random access memory, and/or non-volatile memory such as one or more of phase change random access memory, ferroelectric random access memory, magnetic random access memory, or resistive random access memory.

The device driver 130 may control peripheral devices such as the storage device 140, the modem 150, and the plurality of user interfaces 160 according to a request from the plurality of processors 110. The storage device 140 may include one or more of a fixed type of storage device such as a hard disk drive and/or a solid state drive, or a removable storage device such as an external hard disk drive, an external solid state drive, or a removable memory card.

The modem 150 may provide remote communication with an external device. The modem 150 may perform wireless or wired communication with an external device. The modem 150 may communicate with an external device through at least one of various communication types such as one or more of Ethernet, Wireless Fidelity (Wi-Fi), Long Term Evolution (LTE), and 5-th Generation (5G) mobile communication.

One or more user interfaces 160 may receive information from a user and provide information to the user. The user interfaces 160 may include at least one user output interface such as a display 161 and a speaker 162, and at least one user input interface such as a mouse 163, a keyboard 164, and a touch input device 165.

Instructions (or pieces of code) of the semiconductor process deep learning module 200 may be received, e.g., through the modem 150 and may be stored in the storage device 140. The instructions (or pieces of code) of the semiconductor process deep learning module 200 may be stored in a removable storage device and/or coupled to the computing device 100. The instructions (or pieces of code) of the semiconductor process deep learning module 200 may be loaded from the storage device 140 into the random access memory 120 and executed.

Any or all of the elements described with reference to FIG. 1 may communicate with any or all other elements described with reference to FIG. 1. For example, any element may engage in one-way and/or two-way and/or broadcast communication with any or all other elements in FIG. 1, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

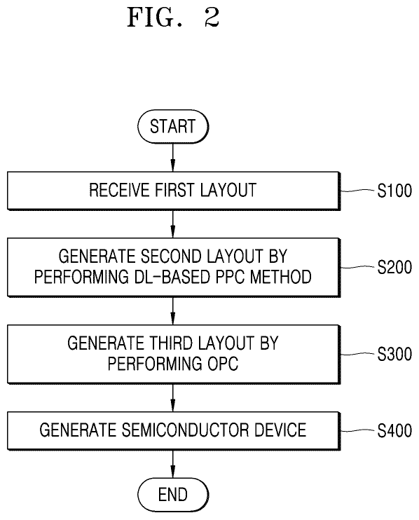

FIG. 2 is a flowchart of a process of generating a layout, performed by the semiconductor process deep learning module of FIG. 1. The process is described with reference to FIG. 1 together.

Referring to FIG. 2, first, the semiconductor process deep learning module 200 may receive a first layout in operation S100. For example, the first layout may be or may correspond to a target layout desired to be obtained during After Cleaning Inspection (ACI). In more detail, the first layout may be a target layout (target ACI) desired to be obtained from the ACI. ACI may actually refer to an inspection after an etching process or after an etching and cleaning process for forming a pattern on a substrate.

The operation of receiving the first layout (S100) may correspond to a process of connecting measurement ACI data to the first layout. For example, one or more of polygons such as rectangles and/or concave shapes, coordinates such as Euclidean coordinates, vertices, and/or edges of the first layout may be converted into a two-dimensional and/or three-dimensional matrix format, and may be linked to data of the measurement ACI.

Next, the semiconductor process deep learning module 200 may generate a second layout by performing process proximity correction (PPC) on the first layout in operation S200. PPC may be performed by performing deep learning-based inference on a plurality of patterns of the first layout. The second layout may be or may correspond to a target layout of a photoresist desired to be obtained during After Development Inspection (ADI). ADI may substantially refer to inspection after a photo (photolithographic) process for forming a photoresist pattern on a substrate. The photo process may include an exposure process and a development process.

In some example embodiments, the ADI may refer to an inspection done before an etching process such as before a subsequent dry etching and/or wet etching process. In some example embodiments, an ADI may correspond to a pattern formed (or to be formed) on a substrate in photoresist, prior to an ACI. Alternatively or additionally, in some example embodiments, an ADI may correspond to a pattern formed (or to be formed) on a substrate in photoresist, prior to an ion implantation process. Example embodiments are not limited thereto.

Through PPC, deformation of the shape of a semiconductor pattern due to the influence of features of the patterns and/or the influence of the etching skew during etching may be compensated for or at least partly compensated for. For example, through PPC, shape deformation during etching may be compensated for in advance by pre-deforming the shape of a portion expected to be deformed in a specific pattern and reflecting the pre-deformed shape in a layout.

Next, the semiconductor process deep learning module 200 may generate a third layout by performing optical proximity correction (OPC) on the second layout in operation S300. The third layout may be a layout of a photo mask.

Through OPC, deformation of the shape of the photoresist pattern due to the influence of features of the patterns to be generated and the effect of the skew may be compensated for.

For example, through OPC, the deformation of the shape during exposure may be compensated for or at least partially compensated for in advance by pre-deforming the shape of a portion expected to be deformed in a specific pattern and reflecting the pre-deformed shape in a layout. For example, one or more of serifs, anti-serifs, or sub-resolution assist features (SRAFs) such as but not limited to inriggers or outriggers may be added to the third layout.

Next, semiconductor devices may be created (or manufactured) based on the third layout in operation S400. For example, an optical rule check (ORC) is performed on an OPC-ed layout to determine the final OPC-ed layout. The ORC may include or be based upon, for example, one or more of Root Mean Square (RMS) calculation for Critical Dimension (CD) error, Edge Placement Error (EPE) calculation, pinch error check, bridge error check, and the like. The items inspected in the ORC are not limited to the above items.

Subsequently, the final OPC-ed layout may be handed over to as Mask Tape-Out (MTO) design data to manufacture a mask, for example to a mask team to create the mask.

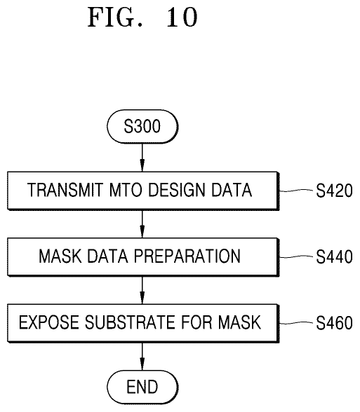

In some example embodiments, the MTO may include etching a chrome-on-glass blank substrate; example embodiments are not limited thereto. Subsequently one or more of a photo process, an etching process, or the like may be performed using the mask to form a pattern on a substrate such as a wafer to thereby manufacture a semiconductor device. In a semiconductor device manufacturing method according to various example embodiments, a semiconductor device may refer to a mask or a photomask, and a semiconductor device on a wafer may be manufactured using a mask. A mask manufacturing method is described in detail in the description with reference to FIG. 10.

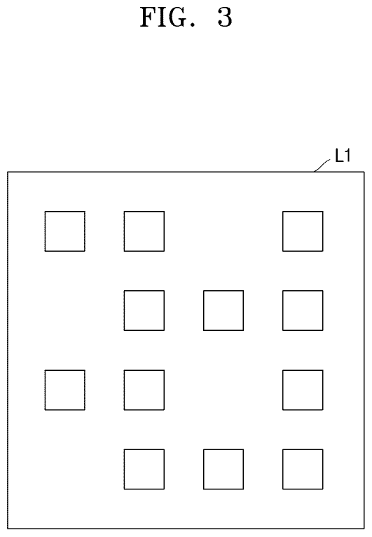

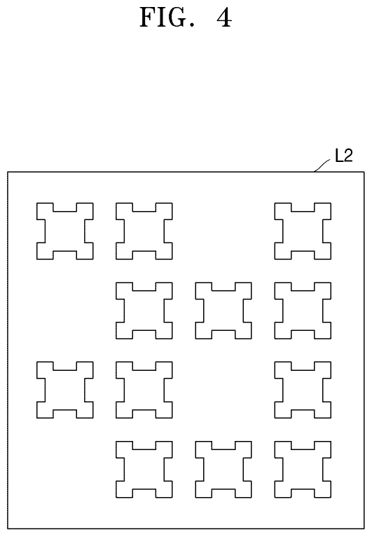

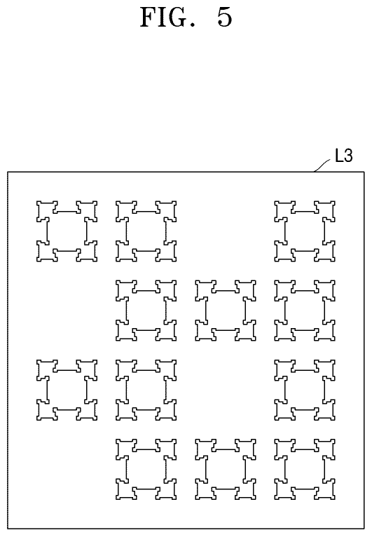

FIGS. 3 to 5 are conceptual diagrams of layouts in respective operations of FIG. 2, wherein FIG. 3 corresponds to a first layout, FIG. 4 corresponds to a second layout, and FIG. 5 corresponds to a third layout.

Referring to FIG. 3, a first layout L1 may include rectangular patterns such as but not limited to square patterns. For example, the rectangular patterns may be patterns of vias or contacts. In some example embodiments, the first layout L1 may be a layout for generating vias. The first layout L1 may be a target layout intended to be acquired in ACI. The patterns included in the first layout L1 are not limited to vias and/or contacts. In addition, shapes of patterns of the vias are not limited to rectangles or squares, and may be other polygonal structures in some example embodiments.

As described below, in the semiconductor device manufacturing method according to inventive concepts, PPC is performed using a visual transformer (ViT) algorithm, and thus the first layout L1 may have, for example, a graphic design system (GDS such as GDSII) vector graphics format.

Referring to FIG. 4, patterns of a second layout L2 may have deformed shapes from the patterns of the first layout L1 of FIG. 3, e.g., with the addition of further serifs. The second layout L2 may be or may correspond to a target layout intended to be acquired by ADI. In FIG. 4, the patterns are all illustrated as deformed into the same shape. However, this is simply an example of description, and in reality, according to positions of the patterns, the patterns may be deformed into different shapes.

Referring to FIG. 5, patterns of a third layout L3 may have deformed shapes from the patterns of the second layout L2 of FIG. 4. The third layout L3 may be or may correspond to a layout for a mask. For example, the patterns of the third layout L3 may correspond to patterns to be formed on a mask. In FIG. 5, also, it is shown that the patterns are deformed in the same shape. However, FIG. 5 is also simply an example for description, and in fact, according to positions of the patterns, the patterns may be deformed into different shapes.

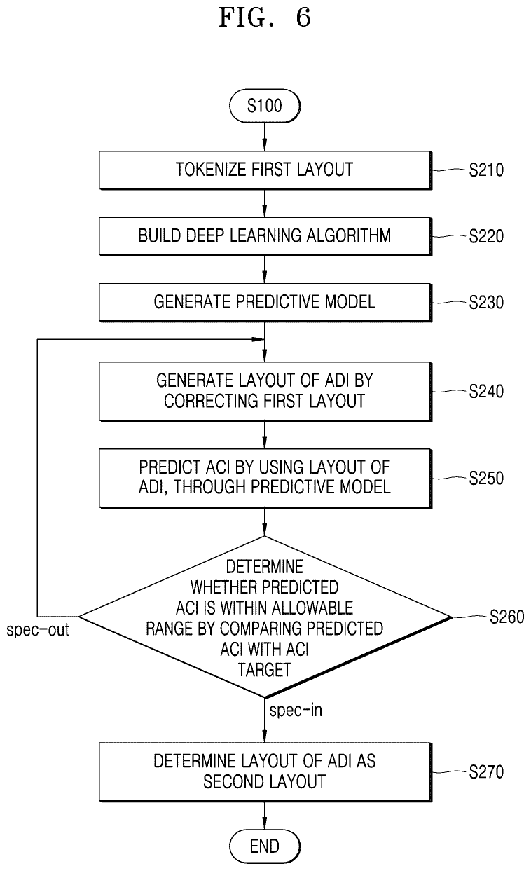

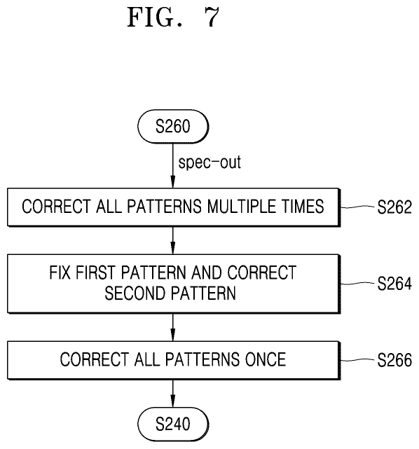

FIG. 6 is a detailed flowchart of the operation of generating the second layout of FIG. 2, and FIG. 7 is a detailed flowchart of the operation of correcting the first layout of FIG. 6. The operations are described with reference to FIGS. 1 to 5 together.

Referring to FIGS. 6 and 7, in the semiconductor device manufacturing method according to various example embodiments, in the generating of the second layout (S200), first, the first layout is tokenized in operation S210. For example, a plurality of polygons in an image of the first layout may be set as tokens. Alternatively or additionally, in some example embodiments, one or more of coordinates such as Euclidean coordinates and/or polar coordinates, vertices, and/or edges of each of a plurality of polygons in the image of the first layout may be set as tokens. Each of the plurality of tokens may collectively or independently have, for example, a form of a two-dimensional matrix and/or a three-dimensional matrix (or referred to as a tensor).

For example, one token among the plurality of tokens may be set as a reference token, and a plurality of tokens within a radius (such as a dynamically determined, or, alternatively, predetermined) radius from the reference token may be set as a data set. For example, the radius may be about 5 micrometers or less (e.g., 5 micrometers or less on the photomask, or 5 micrometers or less on the wafer). When the size of the data set increases, the number of tokens included in the data set increases and accordingly the accuracy of calculation may decrease and/or the amount of calculations may increase.

Next, the semiconductor process deep learning module 200 builds a deep learning algorithm based on the tokenized first layout in operation S220. For example, the semiconductor process deep learning module 200 may determine an input order of tokens in the data set based on the reference token. This may correspond to an operation of tagging location information of an encoder of a transformer algorithm. When there is a criterion for determining the input order of a plurality of tokens, even when the same data set is input multiple times, the plurality of tokens may always be input to the transformer algorithm in the same order.

For example, the semiconductor process deep learning module 200 may introduce polar coordinates, set the reference token as the origin, and set the input order of the plurality of tokens in the data set based on polar coordinates (r, θ). For example, the input order of the plurality of tokens may be determined based on a distance of a token from the reference token and/or an angle between a token and the reference token.

However, a method of determining the input order of a plurality of tokens is not limited thereto, and various methods may additionally or alternatively be used. For example, PointNet may be used.

Next, the semiconductor process deep learning module 200 may generate a predictive model through a deep learning-based algorithm based on the tokenized first layout in operation S230. In order to improve the performance of the predictive model, inference based on, for example, linear regression may be performed. Thereafter, inference based on nonlinear regression may be performed based on the result of the linear regression. For example, the ACI may be predicted using information of a CD and/or a substructure of each of a plurality of patterns.

For example, linear regression may be performed based on information of one token among a plurality of tokens in the data set. For example, linear regression may be performed based on reference token information. Here, information of a token may include information about relative coordinates, size, and/or substructure (for example, a word line and/or a bit line) of the token.

Inference based on linear regression is characterized in that an inference result thereof converges to a single point. On the other hand, regarding inference based on nonlinear regression, an inference result thereof may be two or more points; for example, the inference result may oscillate and/or diverge. In order to prevent or reduce the likelihood that the inference result from oscillating or diverging, the semiconductor process deep learning module 200 may first perform inference based on linear regression. Such inferences using deep learning may not be practically performed without the use of one or more processors.

The accuracy of inference based on linear regression may be lower than that of inference based on nonlinear regression. Accordingly, the semiconductor process deep learning module 200 may further perform inference based on nonlinear regression based on the result of linear regression-based inference. Since inference is started from the result of the linear regression-based inference, inference based on nonlinear regression may approach the nearest inference point without oscillation or divergence. Accordingly, the semiconductor process deep learning module 200 may perform inference with improved accuracy and/or improved stability. For example, the semiconductor process deep learning module 200 may complement the correction convergence and the performance of a predictive model to each other.

However, since the semiconductor process deep learning module 200 is based on deep learning and does not include a process of extracting features, the semiconductor process deep learning module 200 may perform linear regression-based inference based only on data of a reference token.

Unlike the linear regression and nonlinear regression described above, or in addition to the linear regression and nonlinear regression described above, at least one of various algorithms such as a transformer algorithm and/or the like may be used. The semiconductor process deep learning module 200 according to some example embodiments may be configured to perform inference by using two or more algorithms and execute an ensemble algorithm that selects a more suitable one among inference results.

After generating the predictive model, the first layout may be corrected or at least partly corrected, and a layout of ADI may be generated based on the corrected first layout in operation S240. For example, based on the first layout corresponding to an ACI target, the layout of the ADI may be generated by adjusting parts of patterns themselves, such as sizes and/or shapes of the patterns. The process of generating the layout of the ADI corresponds to a retargeting process, and as described above in the description with reference to FIG. 2, the generated the layout of the ADI may be used as an input for OPC later.

Thereafter, using the layout of the ADI, ACI is predicted through the predictive model in operation S250. Subsequently, by comparing the predicted ACI with the ACI target, in operation S260, it may be determined whether the predicted ACI is within an allowable range. Here, if the difference between the predicted ACI and the ACI target is less than a threshold such as a dynamically determined threshold (or, alternatively, a preset threshold (spec-in)), the predicted ACI may be regarded to be within the allowable range, while if the difference between the predicted ACI and the ACI target is greater than the threshold value (spec-out), the predicted ACI may be regarded to be outside the allowable range.

If the difference is within the allowable range (spec-in), the semiconductor process deep learning module 200 determines the layout of the ADI as a second layout in operation S270 and proceeds to operation S300 of generating a third layout. If the difference is outside the allowable range (spec-out), the semiconductor process deep learning module 200 proceeds to operation S240 of generating a layout of an ADI. Before moving to operation S240 of the generating of the layout of the ADI, the first layout may be corrected by adjusting a plurality of patterns.

The first layout may be corrected by the mathematical expression below.

$$( \begin{matrix}Δ CDX \\ Δ CDY\end{matrix} ) = η {A}^{- 1} ( \begin{matrix}{err}_{x} \\ {err}_{y}\end{matrix} ) \qquad Equation 1$$

Here, ΔCDX denotes a correction amount in a first horizontal direction (X-direction), ΔCDY denotes a correction amount in a second horizontal direction (Y-direction), η denotes a damping parameter, A denotes a linear regression matrix, errₓ denotes an error amount in the first horizontal direction (X-direction), err_{y} denotes an error amount in the second horizontal direction (Y-direction).

The above equation represents, as an example, a correction amount of the first layout based on deep learning with respect to a two-dimensional plane. On a two-dimensional plane, A may be expressed in a 2×2 matrix.

In the above mathematical expression, when the damping parameter is 1, the correction amount in the first horizontal direction (X direction) and/or the correction amount in the second horizontal direction (Y direction) may oscillate or diverge. In order to prevent or reduce the correction amount in the first horizontal direction (X direction) and/or the correction amount in the second horizontal direction (Y direction) from oscillating and/or diverging, the damping parameter may be set to less than 1.

Since most of the plurality of patterns are likely to converge quickly, a Melting-Freezing Optimization (MFO) technique may be used. For example, after correcting all the patterns multiple times in operation S262, the semiconductor process deep learning module 200 may fix first patterns that are within a certain error range and correct only second patterns that are outside the certain error range in operation S264. For example, the error range may be equal to or similar to a length of a data base unit (dbu). For example, the error range may be about 0.1 nm or less. After that, the semiconductor process deep learning module 200 may correct all the patterns once in operation S266.

The semiconductor process deep learning module 200 may repeat operations S262 to S266 until the difference between the ACI of all the corrected patterns and the ACI target is less than or equal to a threshold, that is, until an ACI image of all the corrected patterns becomes acceptable.

In a typical semiconductor device manufacturing or fabrication method, a machine learning-based PPC method is employed. In machine learning-based PPC, a pre-processing process for extracting features is required or used, but there is a concern that different features may be extracted for the same data set, for example depending on users. Therefore, the reliability of a general semiconductor device manufacturing method is likely to be relatively low.

In the method of manufacturing a semiconductor device according to various example embodiments, a deep learning-based process proximity correction method is used, and thus, a process of extracting features is not required or used. Therefore, when the same algorithm is used, the same result may be obtained, and thus, the reliability of the semiconductor device manufacturing method according to various example embodiments may be relatively high.

Alternatively or additionally, according to the semiconductor device manufacturing method according to example embodiments, as a transformer algorithm, which is mainly used for natural language processing, is used, vector graphics may be used as input data without a rasterization process. Accordingly, an error occurring in the process of rasterizing data is removed, and the reliability of the semiconductor device manufacturing method may be improved, accordingly.

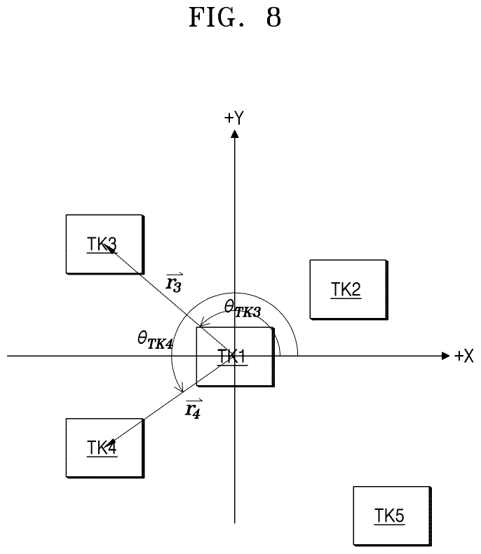

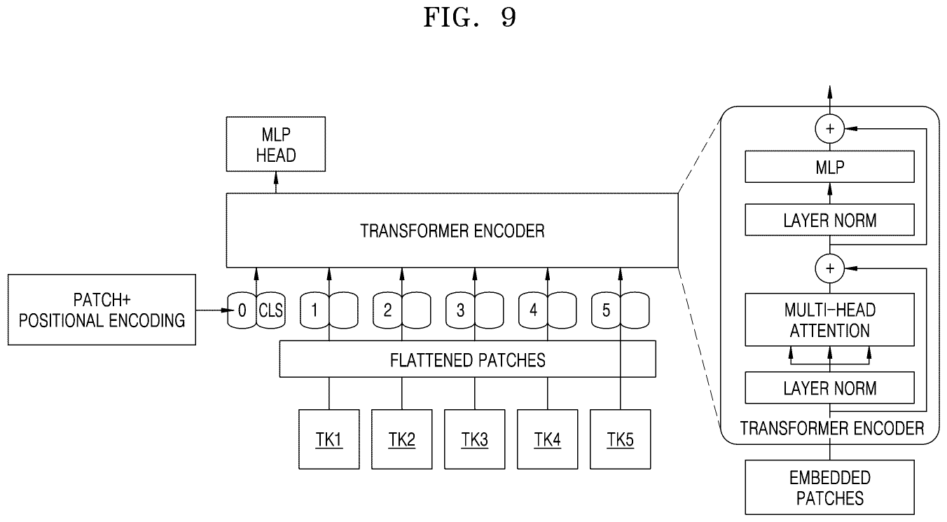

FIG. 8 is a diagram illustrating setting an input order of a plurality of tokens, according to some example embodiments, and FIG. 9 is a diagram illustrating configuring a deep learning algorithm, according to some example embodiments. The operations are described with reference to FIGS. 1 to 6 together.

Referring to FIG. 8, each of the plurality of polygons of the first layout may be set as a token. For example, the first layout may include first to fifth tokens TK1, TK2, TK3, TK4, and TK5. One of the plurality of tokens may be set as a reference token. For example, the first token TK1 may be set as the reference token. In some example embodiments, the reference token may be determined randomly; however, example embodiments are not limited thereto, and the reference token may be determined based on properties of the reference token relative to other tokens.

A plurality of tokens within a certain radius from the reference token may be set as a data set. FIG. 8 illustrates a case in which the first to fifth tokens TK1, TK2, TK3, TK4, and TK5 are disposed in a data set, as an example.

If the input order of the plurality of tokens is changed, a result value of the deep learning algorithm may change, and thus, the input order of the plurality of tokens needs to be or is expected to be determined. For example, the input order of the plurality of tokens may be determined according to a position of each of the plurality of tokens.

For example, the first token TK1, which is the reference token, may be set as an origin, and the first to fifth tokens TK1, TK2, TK3, TK4, and TK5 may be displayed on a polar coordinate system. Then, a distance r and an angle θ of each token with respect to the reference token may be calculated. Prior to calculating the distance r and the angle θ, the highest priority may be set to the reference token. The angle θ may be determined as an angle formed between a radius vector of each token and a particular axis such as a positive X axis (+X).

When the second to fifth tokens TK2, TK3, TK4, and TK5 are arranged in order of distance from the reference token, the second token TK2 is closest to the reference token and may be set in the order following the reference token. The third and fourth tokens TK3 and TK4 may be spaced apart from the reference token by the same distance (same r). Accordingly, the priority of the third and fourth tokens TK3 and TK4 may be set based on the angle θ.

Since an angle θ_{TK3} of the third token TK3 is less than an angle θ_{TK}4 of the fourth token TK4, a higher priority may be given to the third token TK3 than the fourth token TK. As described above, the angle θ_{TK3} of the third token TK3 may denote an angle between the positive X-axis and a radius vector [symbol] of the third token TK3, and the angle θ_{TK4} of the fourth token TK4 may denote an angle formed by the positive X-axis and a radius vector ( [symbol] ) of the fourth token TK4. Lastly, the fifth token TK5 is the farthest from the reference token (largest r), and thus, the lowest priority may be given thereto.

Referring to FIG. 9, the deep learning algorithm may include a transformer algorithm. For example, the deep learning algorithm may include an attention algorithm or a combination of a transformer algorithm and an attention algorithm. The transformer algorithm and/or the attention algorithm may assign a weight to a specific part of input data, enabling to accurately or more accurately identify the relationship between a plurality of tokens. FIG. 9 illustrates the use of a vision transformer algorithm as an example.

In a vision transformer algorithm, encoding of location information of a plurality of tokens may be performed. When the order of a plurality of tokens in a data set is determined, the transformer algorithm may be performed based on the order. As described above, each of the plurality of tokens may be input to the transformer algorithm and/or the attention algorithm in the form of, for example, a two-dimensional matrix or a three-dimensional matrix (also referred to as a tensor). A Special Classification (CLS) token denotes a token used as a first token of an input sequence.

An encoder of the vision transformer algorithm may include one or more of multi-head attention, layer normalization (also called layer norm), and feed-forward (or Multi-Layer Perceptron (MLP)). The encoder of the vision transformer algorithm may include N (where N is a natural number equal to or greater than 1) layers. For example, the encoder may include N feed-forwards and multi-head attention.

Multi-head attention may include connecting a plurality of self-attentions in parallel. A self-attention function may specify information to be paid attention to in an input sequence. The self-attention function may calculate similarity with all keys for a given query and reflect the similarity in each value mapped with the key.

Layer normalization may normalize an input. The vision transformer algorithm normalizes the input before attention.

Information paid attention to by the self-attention function may be delivered to feed-forward. The feed-forward includes a feed-forward neural network, and a conversion sequence of an input sequence may be output by the feed-forward neural network. Feed-forward may include a plurality of hidden layers.

FIG. 10 is a flowchart schematically illustrating a process of a mask manufacturing method, according to some example embodiments. FIG. 10 illustrates a case where a semiconductor device of FIG. 2 is a mask. The details already described in the description with reference to FIGS. 1 to 9 are briefly described or omitted.

Referring to FIG. 10, an image of the final OPC-ed layout is transmitted to a mask manufacturing team or facility as MTO design data in operation S420. The third layout corresponds to an OPC-ed layout and may also correspond to a final ORC-ed layout that has passed an ORC. In general, MTO may refer to handing over final mask data obtained through OPC to a mask manufacturing team or facility to request or perform mask manufacturing. Accordingly, the MTO design data may be substantially the same as data about the image of the final OPC-ed layout obtained through OPC. The MTO design data may have a graphic data format used in electronic design automation (EDA) software and/or the like. For example, MTO design data may have data formats such as Graphic Data System (GDS such as GDSII) and/or Open Artwork System Interchange Standard (OASIS).

Then, mask data preparation (MDP) is performed in operation S440. MDP may include, for example, i) format conversion called fracturing, ii) augmentation such as barcode for machine reading, standard mask patterns for inspection, job decks, etc., and iii) verification in automatic and manual manners. Here, a job-deck may refer to creating a text file related to a series of commands, such as one or more of arrangement information of multiple mask files, a standard dose, and an exposure speed or method.

Format conversion, for example, segmentation, may refer to a process of segmenting MTO design data by region and changing the data into a format for an electron beam exposure machine. Segmentation may include, for example, data manipulation such as one or more of scaling, data sizing, data rotation, pattern reflection, and color inversion. In the conversion process through segmentation, data may be corrected for numerous systematic errors that may occur somewhere during a transfer process from design data to an image on a wafer. A data correction process for the systematic errors is called mask process correction (MPC), and may include, for example, line width control called CD control and/or an operation to increase pattern placement precision. Thus, segmentation may contribute to improving the quality of the final mask and may also be a pre-performed process for MPC. Here, systematic errors may be caused by distortion generated in an exposure process, a mask development and etching process, and a wafer imaging process.

MDP may include MPC. As described above, MPC refers to a process of correcting an error generated during an exposure process, for example, a systematic error. Here, the exposure process may be a concept that generally includes electron beam writing, developing, etching, baking, and the like. Additionally or alternatively, data processing may be performed prior to the exposure process. Data processing is a kind of pre-processing of mask data, and may include a grammar check on mask data, prediction of an exposure time, and the like.

After preparing the mask data, a substrate (e.g., a glass substrate with chrome deposited thereon) for a mask is exposed based on the mask data in operation S460. Here, exposure may refer to, for example, electron beam writing. Here, the electron beam writing may be performed in a gray writing method using, for example, a multi-beam mask writer (MBMW). In some example embodiments, electron beam writing may be performed using a variable shape beam (VSB) exposure machine.

After the mask data preparation operation and before the exposure process, a process of converting the mask data into pixel data may be performed. Pixel data is or corresponds to data directly used for actual exposure, and may include data about a shape that is an exposure object and data about a dose assigned thereto. Here, the data about shapes may be bit-map data obtained by converting shape data, which is vector data, through rasterization or the like.

After the exposure process, a series of processes are performed to complete the mask. The series of processes may include, for example, developing, etching, and cleaning processes. In addition, the series of processes for manufacturing of a mask may include one or more of a measurement process, a defect inspection, or defect repair process. In some example embodiments, a pellicle application process may be included. The pellicle application process may refer to a process of attaching a pellicle to a mask surface to protect the mask from subsequent contamination during the delivery and service life of the mask when it is confirmed that there are no contaminant particles or chemical stains through final cleaning and inspection.

According to the mask manufacturing method according to various example embodiments, a mask layout with improved reliability may be generated through a deep learning-based PPC method and OPC. As a result, according to the mask manufacturing method of the various example embodiments, a semiconductor device with improved reliability may be manufactured.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been particularly shown and described with reference to embodiments thereof, it will be understood that various changes in form and details may be made therein without departing from the spirit and scope of the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. A deep learning-based process proximity correction method comprising:
receiving a first layout associated with an After Cleaning Inspection (ACI), the first layout including a plurality of patterns associated with manufacturing a semiconductor device;
generating a predictive model based on the plurality of patterns, through deep learning;
generating a layout associated with an After Development Inspection (ADI) by correcting the first layout; and
predicting ACI by using the layout of the ADI, through the predictive model.

2. The deep learning-based process proximity correction method of claim 1, wherein the generating of the predictive model based on the plurality of patterns through deep learning, comprises a tokenization operation of setting the plurality of patterns to a plurality of tokens, respectively.

3. The deep learning-based process proximity correction method of claim 2, wherein a plurality of polygons in the first layout are set to the plurality of tokens, respectively.

4. The deep learning-based process proximity correction method of claim 2, wherein each of the plurality of tokens independently has a two-dimensional or three-dimensional matrix form.

5. The deep learning-based process proximity correction method of claim 1, wherein the predictive model comprises a transformer algorithm.

6. The deep learning-based process proximity correction method of claim 2, wherein the generating of the predictive model comprises setting an input order of the plurality of tokens with respect to the predictive model.

7. The deep learning-based process proximity correction method of claim 6, wherein, in the setting of the input order of the plurality of tokens, the input order is set according to arrangement positions of the plurality of tokens.

8. The deep learning-based process proximity correction method of claim 6, wherein, in the setting of the input order of the plurality of tokens, a closer a distance of a token to a reference token and a smaller an angle between a radius vector of each of the plurality of tokens and a positive X-axis corresponds to a higher priority of the input order given to the plurality of tokens.

9. The deep learning-based process proximity correction method of claim 1, wherein the generating of the predictive model comprises:
performing a first deep learning-based inference based on linear regression on a plurality of tokens; and
performing a second deep learning-based inference based on nonlinear regression on a result of the first deep learning-based inference.

10. The deep learning-based process proximity correction method of claim 9, wherein the performing of the first deep learning-based inference is based on information of one of the plurality of tokens.

11. A deep learning-based process proximity correction method comprising:
receiving a first layout associated with an After Cleaning Inspection (ACI), the first layout including a plurality of patterns for manufacturing a semiconductor device;
generating a second layout by performing deep learning (DL)-process proximity correction (PPC) based on the plurality of patterns of the first layout; and
generating a third layout by performing optical proximity correction (OPC) on the second layout.

12. The deep learning-based process proximity correction method of claim 11, wherein the generating of the second layout comprises:
generating a predictive model based on the plurality of patterns, through deep learning;
generating a layout associated with an After Development Inspection (ADI) by correcting the first layout; and
predicting ACI by using the layout of the ADI, through the predictive model.

13. The deep learning-based process proximity correction method of claim 12, wherein the predicting of the ACI is performed based on critical dimension (CD) information of each of the plurality of patterns.

14. The deep learning-based process proximity correction method of claim 12, wherein the first layout is corrected by the following formula:
$$( \begin{matrix}Δ CDX \\ Δ CDY\end{matrix} ) = η {A}^{- 1} ( \begin{matrix}{err}_{x} \\ {err}_{y}\end{matrix} )$$
(where ΔCDX denotes a correction amount in a first horizontal direction (X-direction), ΔCDY denotes a correction amount in a second horizontal direction (Y-direction), η denotes a damping parameter, A denotes a linear regression matrix, errₓ denotes an error amount in the first horizontal direction (X-direction), err_{y} denotes an error amount in the second horizontal direction (Y-direction)).

15. The deep learning-based process proximity correction method of claim 14, wherein the damping parameter is less than 1.

16. The deep learning-based process proximity correction method of claim 11, further comprising:
correcting a plurality of patterns multiple times, such that, after correcting the plurality of patterns multiple times, among the plurality of patterns a position of at least one first pattern is fixed within an error range; and
further correcting one or more second patterns having a position greater than or equal to the error range.

17. The deep learning-based process proximity correction method of claim 16, wherein the error range is equal to or less than 0.1 nm.

18. The deep learning-based process proximity correction method of claim 12, further comprising, after the predicting of ACI through the predictive model:
determining whether a difference between the predicted ACI and an ACI target is within an allowable range;
in response the difference being outside the allowable range, proceeding to the generating of a layout of the ADI; and
determining the layout of the ADI as the second layout and proceeding to the generating of the third layout, in response to the difference being within the allowable range.

19. A mask manufacturing method comprising:
receiving a first layout including a plurality of patterns associated with manufacturing a semiconductor device;
generating a second layout by performing deep learning-based process proximity correction on the first layout;
generating a third layout by performing optical proximity correction on the second layout;
transmitting the third layout as mask tape-out (MTO) design data;
preparing mask data based on the MTO design data; and
exposing a substrate associated with a mask based on the mask data.

20. The mask manufacturing method of claim 19, wherein the generating of the second layout comprises:
converting each of the plurality of patterns independently into a two-dimensional or three-dimensional matrix; and
inputting the two-dimensional or three-dimensional matrix into a transformer algorithm.
